(19) United States
(12) Patent Application Publication
(10) Pub. No.: US 2009/0310302 A1
(43) Pub. Date: Dec. 17, 2009

(54) HEAT-DISSIPATING STRUCTURE HAVING AN EXTERNAL FAN

(75) Inventors: Chien-Da Hu, Jhongli City (TW); Hsuan-Liang Liu, Gueishan Township (TW)

Correspondence Address: NIKOLAI & MERSEREAU, P.A., 900 SECOND AVENUE SOUTH, SUITE 820, MINNEAPOLIS, MN, 55402, US

(73) Assignee: ENERMAX TECHNOLOGY CORPORATION, Taoyuan City (TW)

(21) Appl. No.: 12/140,753

(22) Filed: Jun. 17, 2008

(51) Int. Cl. H05K 7/20

(52) U.S. Cl. 361/695

(57) ABSTRACT

A heat-dissipating structure having an external fan includes a casing, a connecting piece and a heat-dissipating fan. The casing is provided with a plurality of heat-dissipating holes. The connecting piece is provided outside the casing. The heat-dissipating fan is assembled on the connecting piece to correspond to the positions of the heat-dissipating holes. An accommodating space is formed between the heat-dissipating fan and the casing. Via this arrangement, the heat-dissipating fan can be provided outside the casing to cooperate with the heat-dissipating holes, thereby dissipating the heat within the casing quickly.

### BACKGROUND OF THE INVENTION

1. Field of the Invention

The present invention relates to a heat-dissipating structure having an external fan, and in particular to a heat-dissipating structure having a heat-dissipating fan provided outside a casing to facilitate the cooling of internal elements.

2. Description of Related Art

There are many kinds of circuit boards and electronic elements in a computer host. Since the chips, integrated circuits or other electronic elements on the circuit board generate a lot of heat during operation, the temperature within the computer host will rise. If the temperature exceeds the upper limit of the normal operation parameter of each respective electronic element, the respective electronic element may become inactive, causing the computer host to break down. Therefore, heat sinks and heat-dissipating fans may be additionally mounted in the computer host, thereby dissipating the heat generated by the electronic elements by means of compulsive cooling. In this way, the normal operation of the computer host can be maintained.

Please refer to FIG. 1. The interior of the casing 10a of the conventional computer host is usually provided with a main board 20a. A central processor (not shown) is mounted on the main board 20a to process the data transmitted from respective device. Since the central processor is operated at high frequency, its temperature is very high. In order to solve the problem of central processor overheating, a common solution is to utilize the combination of heat sinks and heat-dissipating fans, thereby reducing the temperature of the central processor to maintain the normal operation of the computer host.

A plurality of interface card expansion slots 21a (conforming to the standard of PCI, PCI-E) is provided on the main board 20a, so that the interface cards (not shown) such as a display card, a sound card, a network card or the like can be inserted into the expansion slots to be electrically connected with the main board 20a.

The back plate 11a of the casing 10a is provided with a plurality of slots 12a into which the interface cards can be inserted. The slots 12a are provided with a plurality of shields 13a for shielding the interior of the casing 10a.

According to the above, the heat-dissipating means within the casing 10a is directed to perform the heat dissipation for heat-generating elements such as a central processor. However, since the region in which the interface card is located is shielded by the back plate 11a and the shields 13a, the space therein is so restricted that the convention of air in this region cannot be produced efficiently. Furthermore, with the increase of the operating speed of the computer host, the operating speed of the interface card is also increased. As a result, more heat will be generated. Therefore, it is an important issue to provide an efficient solution for heat dissipation.

Consequently, because of the above limitation resulting from the technical design of prior art, the inventor strives via real world experience and academic research to develop the present invention, which can effectively improve the limitations described above.

### SUMMARY OF THE INVENTION

The object of the present invention is to provide a heat-dissipating structure having an external fan, in which a heat-dissipating fan is provided outside a casing with a certain distance. With the cooperation of the heat-dissipating fan and heat-dissipating holes provided on the casing, the heat within the casing can be dissipated efficiently.

In order to achieve the above objects, the present invention provides a heat-dissipating structure having an external fan, which includes a casing provided with a plurality of heat-dissipating holes; a connecting piece provided outside the casing; and a heat-dissipating fan assembled on the connecting piece to correspond to the positions of the heat-dissipating holes. An accommodating space is formed between the heat-dissipating fan and the casing.

The present invention has advantageous features as follows. Although the internal space of the casing is limited, the present invention is provided with a heat-dissipating fan externally. In this way, the convention of air in this region can be improved efficiently, and the heat-dissipating efficiency can be improved.

In order to further understand the characteristics and technical contents of the present invention, a detailed description relating thereto will be made with reference to the accompanying drawings. However, the drawings are illustrative only, but not used to limit the scope of the present invention.

### BRIEF DESCRIPTION OF THE DRAWINGS

FIG. 1 is a perspective view showing a casing of a conventional computer host;

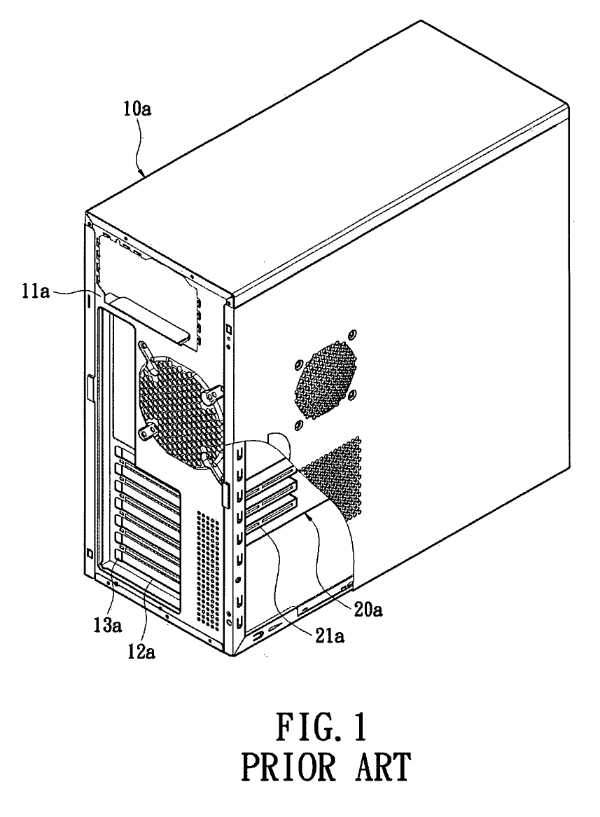

FIG. 2 is an exploded perspective view showing a first embodiment of the heat-dissipating structure having an external fan in accordance with the present invention;

FIG. 3 is an assembled perspective view showing the first embodiment of the heat-dissipating structure having an external fan in accordance with the present invention;

FIG. 4 is an exploded perspective view showing a second embodiment of the heat-dissipating structure having an external fan in accordance with the present invention;

FIG. 5 is an assembled perspective view showing the second embodiment of the heat-dissipating structure having an external fan in accordance with the present invention;

FIG. 6 is an exploded perspective view showing a third embodiment of the heat-dissipating structure having an external fan in accordance with the present invention; and

FIG. 7 is an assembled perspective view showing the third embodiment of the heat-dissipating structure having an external fan in accordance with the present invention.

### DETAILED DESCRIPTION OF THE PREFERRED EMBODIMENTS

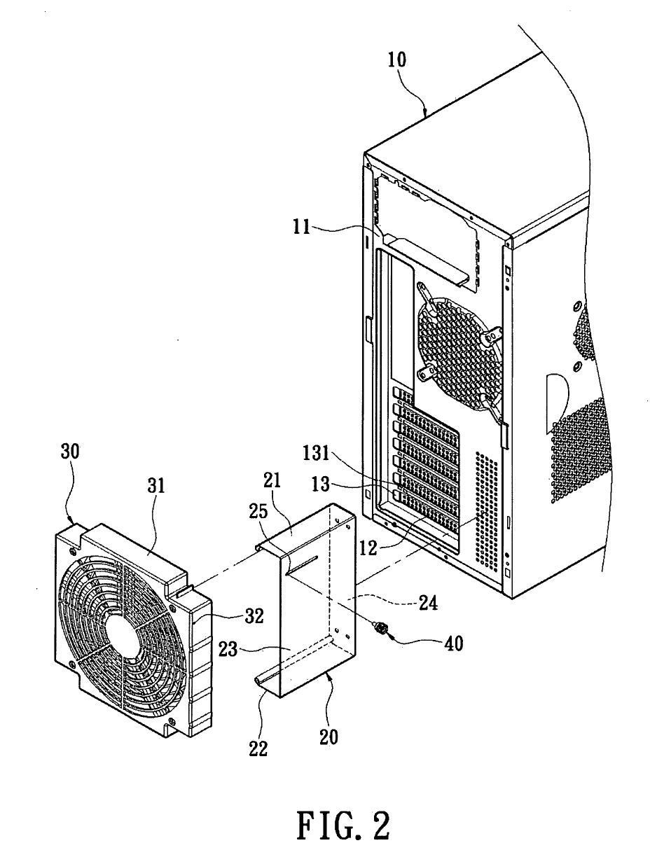

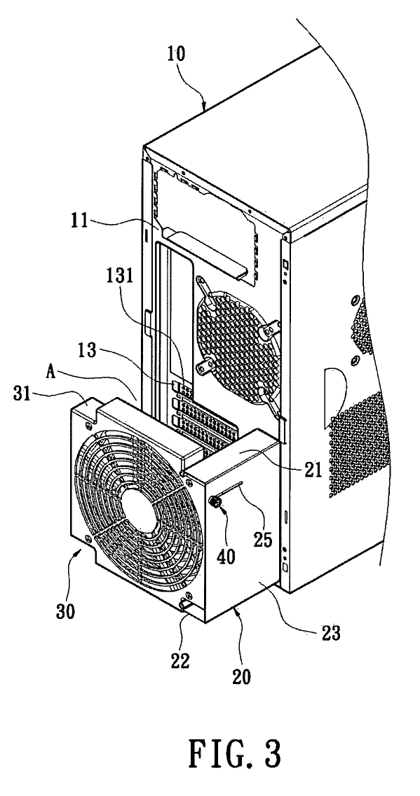

Please refer to FIGS. 2 and 3, which show a first embodiment of a heat-dissipating structure having an external fan. The heat-dissipating structure having an external fan of the present invention includes a casing 10, a connecting piece 20, a heat-dissipating fan 30 and a positioning piece 40.

The casing 10 is a hollow box. The interior of the casing is used to accommodate a main board (not shown). The main board is provided thereon with a plurality of interface card expansion slots (not shown) into which the interface cards can be inserted therein. The rear side of the casing 10 has a back plate 11. The bottom of the back plate 11 is provided with a plurality of slots 12 through which the interface cards can pass. The casing 10 and the slots 12 are provided with a plurality of shields 13 for sealing the slots 12. Each shield 13 is provided with a plurality of heat-dissipating holes 131 for ventilation.

The connecting piece 20 has a top wall 21, a bottom wall 22, a side wall 23 and an end wall 24. The top wall 21 and the bottom wall 22 are located on the top and bottom of the connecting piece 20 respectively. The side wall 23 is connected to one side of the top wall 21 and bottom wall 22 away from the heat-dissipating fan 30. The end wall 24 is connected to one side of the top wall 21 and bottom wall 22 adjacent to the casing 10. The end wall 24 of the connecting piece 20 can be provided on the surface of the back plate 11 of the casing 11 by means of screw components, snap-fitting components and magnetic components. In this way, the connecting piece 20 is arranged outside the casing 10. Of course, the connecting piece 20 can be arranged at other positions of the casing 10.

In the present embodiment, the side wall 23 of the connecting piece 20 is provided with a trough 25. The trough 25 extends to a certain distance in the horizontal direction of the casing 10.

The heat-dissipating fan 30 has a frame 31. One side of the frame 31 adjacent to the connecting piece 20 is provided with a mounting hole 32. The mounting hole 32 corresponds to the trough 25 of the connecting piece 20 and the positioning piece 40 (FIG. 2).

In the present embodiment, the positioning piece 40 is a manual screw, but it is not limited thereto. The positioning piece 40 passes through the trough 25 of the connecting piece 20 and is positioned (i.e. locked) onto the mounting hole 32 of the frame 31 of the heat-dissipating fan 30. With the positioning piece 40 moving in the trough 25, the position of the heat-dissipating fan 30 can be adjusted. In this way, the heat-dissipating fan 30 is arranged on the connecting piece 20 with a certain distance from the casing 10, thereby forming an external fan. At the same time, the position of the heat-dissipating fan 30 corresponds to those of the heat-dissipating holes 131.

An open accommodating space A is formed between the heat-dissipating fan 30 and the casing 10, so that external elements (such as signal connecting lines or network lines of a displayer) connected with the casing 10 can pass through the accommodating space. With the above constitution, the heat-dissipating structure having an external fan according to the present invention can be formed.

In operation, a user can utilize the cooperation of the trough 25 and the positioning piece 40 to increase or reduce the distance between the heat-dissipating fan 30 and the casing 10. In this way, the heat-dissipating fan 30 can be arranged in a proper position thereby dissipate the heat within the casing 10 quickly and increase the heat-dissipating efficiency. In other words, the heat-dissipating fan 30 is assembled on the connecting piece 20 with its position adjustable.

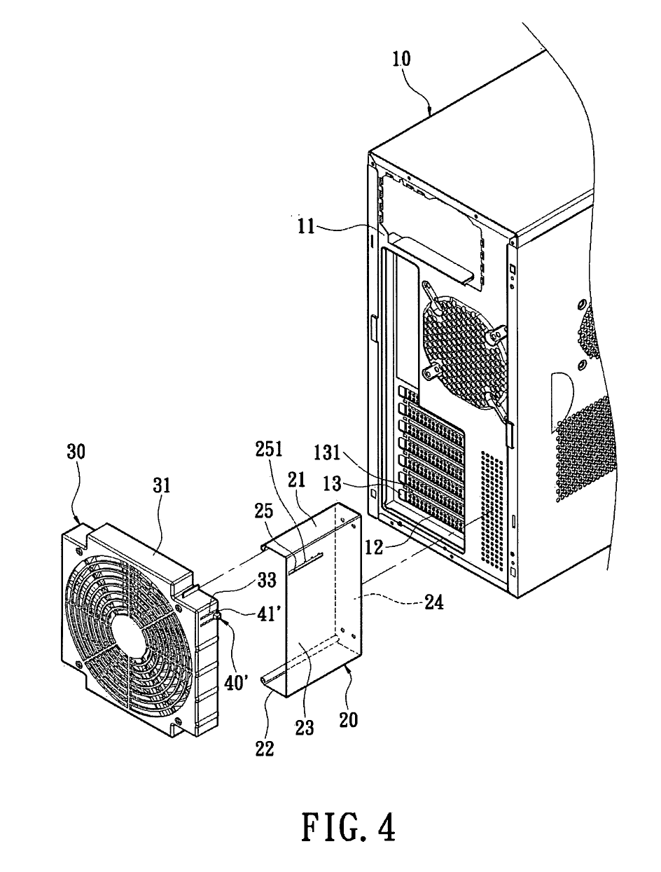

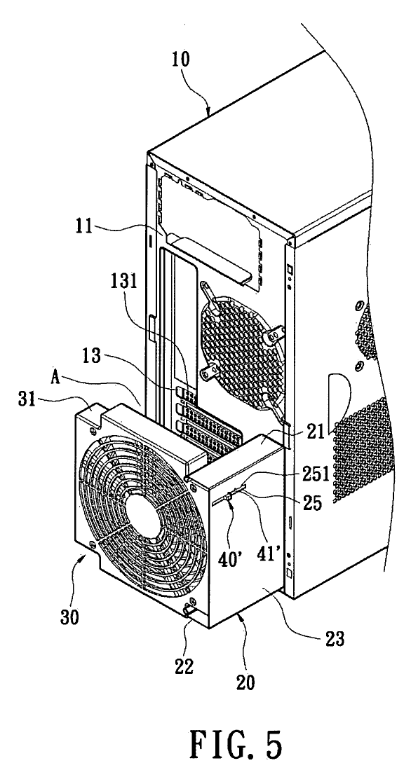

Please refer to FIGS. 4 and 5, which show a second embodiment of the heat-dissipating structure having an external fan according to the present invention. The elements of the second embodiment identical to those of the first embodiment are designated by the same reference numerals. The difference between the second embodiment and the first embodiment is described as follows.

The connecting piece 20 is provided with a plurality of spaced recesses 251 on one side of the trough 25. The recesses 251 are in communication with the trough 25.

The positioning piece 40′ is integrally formed with the frame 31 of the heat-dissipating fan 30. The positioning piece 40′ is provided with a protrusion 41′. By pushing the positioning piece 40′, the heat-dissipating fan 30 can be driven to adjust its position.

The frame 31 is provided with a groove 33 on two opposite sides of the positioning piece 40′ respectively, so that the positioning piece 40′ can be deformed elastically toward the interior of the frame 31.

When the positioning piece 40′ in the trough 25 is pushed, the protrusion 41′ can be inserted into different recesses 251, so that the heat-dissipating fan 30 can be arranged in different positions of the connecting piece 20. In other words, the heat-dissipating fan 30 is assembled on the connecting piece 20 with its position adjustable.

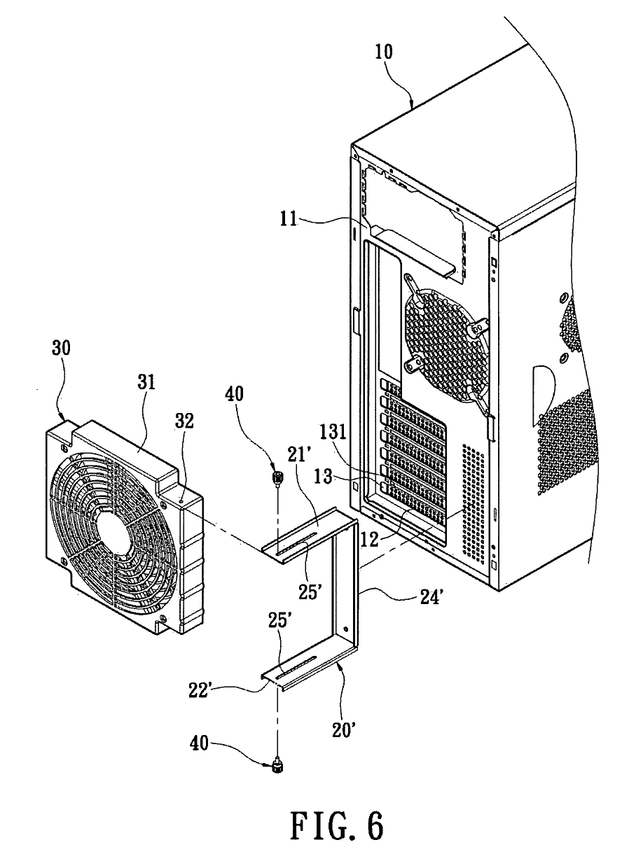

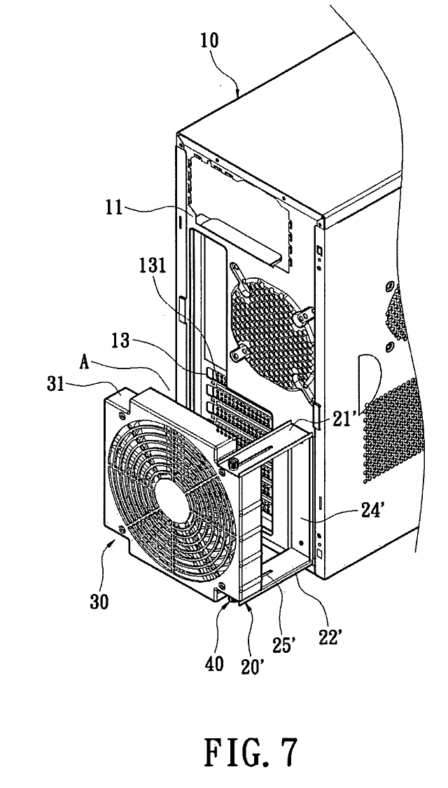

Please refer to FIGS. 6 and 7, which show a third embodiment of the heat-dissipating structure having an external fan according to the present invention. The elements of the third embodiment identical to those in the first embodiment are designated by the same reference numerals. The difference between the third embodiment and the first embodiment is described as follows.

The connecting piece 20′ has a top wall 21′, a bottom wall 22′ and an end wall 24′. The top wall 21′, the bottom wall 22′ and the end wall 24′ are connected to form a U-shaped member. The end wall 24′ can be provided on the surface of the back plate 11 of the casing 10 by means of screw components. Snap-fitting components or magnetic components, so that the connecting piece 20′ can be arranged outside the casing 10.

The top wall 21′ and the bottom wall 22′ of the connecting piece 20′ are each provided with a trough 25′ respectively. The top and bottom of the heat-dissipating fan 30 has mounting holes 32 respectively for cooperating with two positioning pieces 40 (in this case the two positioning pieces 40 are manual screws). The two positioning pieces 40 respectively pass through the two troughs 25′ and are locked to the mounting holes 32 of the heat-dissipating fan 30. The position of the heat-dissipating fan 30 is adjustable by means of the two positioning pieces 40 and the two troughs 25′.

Therefore, according to the heat-dissipating structure having an external fan, with respect to the region in which the internal space of the casing 10 is limited (such as the region in which the interface cards are mounted), a heat-dissipating fan 30 can be provided on the casing 10 externally, thereby improving the circulation of air in this region and increasing the heat-dissipating efficiency.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat-dissipating structure having an external fan, comprising:
a casing provided with a plurality of heat-dissipating holes;
a connecting piece provided outside the casing; and
a heat-dissipating fan provided on the connecting piece to correspond to the positions of the heat-dissipating holes, an accommodating space being formed between the heat-dissipating fan and the casing.

2. The heat-dissipating structure having an external fan according to claim 1, wherein the casing has a back plate, the back plate is provided with a plurality of slots, the slots are provided with a plurality of shields, the hear-dissipating holes are provided on the shields.

3. The heat-dissipating structure having an external fan according to claim 1, wherein the connecting piece is provided outside the casing by means of screw components, snap-fitting components or magnetic components.

4. The heat-dissipating structure having an external fan according to claim 1, further comprising at least one positioning piece, the connecting piece is provided with at least one trough, the positioning piece passes through the trough and is positioned on the heat-dissipating fan.

5. The heat-dissipating structure having an external fan according to claim 4, wherein the positioning piece is a manual screw.

6. The heat-dissipating structure having an external fan according to claim 4, wherein the heat-dissipating fan has a frame, and the frame is provided with at least one mounting holes to be connected with the positioning piece.

7. The heat-dissipating structure having an external fan according to claim 4, wherein the heat-dissipating fan has a frame, and the positioning piece is integrally formed with the frame.

8. The heat-dissipating structure having an external fan according to claim 7, wherein the frame is provided with a groove on two opposite sides of the positioning piece.

9. The heat-dissipating structure having an external fan according to claim 4, wherein the connecting piece is provided with at least one recess on one side of the trough, the recess is in communication with the trough, and the positioning piece is provided with a protrusion that is inserted into the recess.

10. The heat-dissipating structure having an external fan according to claim 1, wherein the accommodating space is open.

11. The heat-dissipating structure having an external fan according to claim 1, wherein the heat-dissipating fan is assembled on the connecting piece with its position adjustable.
